(19) United States
(12) Patent Application Publication
(10) Pub. No.: US 2024/0070350 A1
(43) Pub. Date: Feb. 29, 2024

(54) WORKFLOW SIMULATION WITH ENVIRONMENT SIMULATION

(71) Applicant: International Business Machines Corporation, Armonk, NY (US)

(72) Inventors: Rakesh Rameshrao Pimplikar, Bangalore (IN); Ritwik Chaudhuri, Bangalore (IN); Pranay Kumar Lohia, Bhagalpur (IN); Ramasuri Narayanam, ANDHRA PRADESH (IN); Sameep Mehta, BANGALORE (IN); Gyana Ranjan Parija, New Delhi (IN)

(21) Appl. No.: 17/893,295

(22) Filed: Aug. 23, 2022

(51) Int. Cl. G06F 30/27; G06Q 10/06

(52) U.S. Cl. CPC G06F 30/27; G06Q 10/0633

(57) ABSTRACT

An example operation may include one or more of identifying an external system that passes an input attribute to a process based on a workflow representation of the process, building a simulator of the external system based on attributes of the external system identified from the workflow representation, simulating future values of the input attribute to be passed to the process by the external system based on the simulator of the external system and a previous simulation run of the process performed via a workflow software application, and executing a new simulation of the process via the workflow software application based on the simulated future values of the input attribute.

### BACKGROUND

A business process may include a set or sequence of linked tasks and activities that result in a specific outcome. Prior to implementing a business process, an organization may simulate the business process to understand how it will work. For example, a simulation software application may be used to try a variety of scenarios and solutions which enable a developer to figure out which solution is best for their current needs without impacting production. Furthermore, simulations can also be an effective mechanism for improving existing business processes. For example, simulations may be a cost-effective and low-impact mechanism for finding ways to improve the operations and production of an existing workflow.

In many cases, a business workflow is integrated with external systems such as databases, websites, application programming interfaces (APIs), and the like, which pass input values to the simulator. Furthermore, outputs from the business workflow may be sent back to the external systems for further processing. Because of this interconnection, decisions/actions taken by the workflow may in turn impact future inputs received from the external systems. That is, the input values being fed into the system may change over time as a result of the interactions between the model and the external systems. However, existing simulation software only considers static information about the input variables fed from the external systems to the simulator based on historical data. In reality though, the input variables often change with time due to the interactions between the business process and the external systems. As a result, the workflow simulations may not be accurate because traditional workflow simulations cannot take into account such changing input variables.

### SUMMARY

One example embodiment provides an apparatus that includes a memory configured to store a workflow software application, and a processor configured to one or more of identify an external system that passes an input attribute to a process based on a workflow representation of the process, build a simulator of the external system based on attributes of the external system identified from the workflow representation, simulate future values of the input attribute to be passed to the process by the external system based on the simulator of the external system and a previous workflow simulation of the process performed via a workflow software application, and execute a new workflow simulation of the process via the workflow software application based on the simulated future values of the input attribute.

Another example embodiment provides a method that includes one or more of identifying an external system that passes an input attribute to a process based on a workflow representation of the process, building a simulator of the external system based on attributes of the external system identified from the workflow representation, simulating future values of the input attribute to be passed to the process by the external system based on the simulator of the external system and a previous simulation run of the process performed via a workflow software application, and executing a new simulation of the process via the workflow software application based on the simulated future values of the input attribute.

A further example embodiment provides a computer-readable medium comprising instructions, that when read by a processor, cause the processor to perform one or more of identifying an external system that passes an input attribute to a process based on a workflow representation of the process, building a simulator of the external system based on attributes of the external system identified from the workflow representation, simulating future values of the input attribute to be passed to the process by the external system based on the simulator of the external system and a previous simulation run of the process performed via a workflow software application, and executing a new simulation of the process via the workflow software application based on the simulated future values of the input attribute.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram illustrating a cloud computing environment that interacts with various devices according to an example embodiment.

FIG. 2A is a diagram illustrating abstraction model layers of a cloud computing environment according to an example embodiment.

FIG. 2B is a diagram illustrating a process of simulating a future environment of a process and simulating a workflow of the process based on the simulated future environment according to an example embodiment.

FIGS. 3A-3C are diagrams illustrating examples of a permissioned network according to example embodiments.

FIG. 3D is a diagram illustrating machine learning process via a cloud computing platform according to an example embodiment.

FIG. 3E is a diagram illustrating a quantum computing environment associated with a cloud computing platform according to an example embodiment.

FIG. 4A is a diagram illustrating a process of building an external system simulation model according to an example embodiment.

FIG. 4B is a diagram illustrating a process of identifying hops between attributes and a workflow simulation using a graphical model according to an example embodiment.

FIG. 4C is a diagram illustrating a process of simulating a workflow for a process according to an example embodiment.

FIG. 5 is a diagram illustrating a method of simulating a workflow based on a simulated workflow environment according to an example embodiment.

FIG. 6 is a diagram illustrating an example of a computing system that supports one or more of the example embodiments.

### DETAILED DESCRIPTION

It is to be understood that although this disclosure includes a detailed description of cloud computing, implementation of the teachings recited herein is not limited to a cloud computing environment. Rather, embodiments of the present invention are capable of being implemented in conjunction with any other type of computing environment now known or later developed.

Traditional automation software that is configured to simulate a workflow of a business process may rely on static information being input to the business process. For example, an input from an external system may be determined ahead of time based on historical data fed into a simulation model. The result is a static distribution of input variables from the external system over time. However, in reality such distributions typically change with time. The causes of such changes can be from the process itself that is being simulated. This interdependence between the workflow and the external system is not taken into consideration by traditional workflow automation software.

According to various embodiments, provided herein is a host platform for workflow automation that considers “dynamic” changes to the input variables from external systems over time by exploiting the interdependence between the external systems (and the input variables that they provide) and the values arising/output from the simulation of the business process. The process may be embodied within a simulation model. Meanwhile, the host platform may generate a simulator for an external system (or multiple simulators for multiple external systems) which are configured to generate “simulated” input values for the business process under simulation. The simulator for the external system can predict input variables for the process under simulation based on a changing distribution of the input variables as opposed to static distribution of input variables in the related art. Because the influence/interdependence of the simulation itself on the external system is considered by the simulation platform described herein, the simulated results of the process may be more accurate providing for a better quality workflow automation software application in comparison to the related art.

For example, the host platform may host a software that implements a framework for creation of the environment in which multiple business workflows would run. The host platform may generate a prediction of a future snapshot of the environment of the process by predicting the attributes that are affecting the simulation model of the process and vice-versa. The interdependence between the process being simulated and the external system providing input variables (the environment) to the process being simulated can be realized based on a k-hop distance between the external system (the value provided by the external system) and the simulation workflow in a graphical model. For example, for the prediction of the future values of the external attributes when simulated the workflow, the host platform may use the k-hop distance between the attributes and the simulation outcome.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Examples of cloud computing characteristics that may be associated with the example embodiments include the following.

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Examples of service models that may be associated with the example embodiments include the following:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Examples of deployment models that may be associated with the example embodiments include the following:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service-oriented with a focus on statelessness, low coupling, modularity, and semantic interoperability. At the heart of cloud computing is an infrastructure that includes a network of interconnected nodes.

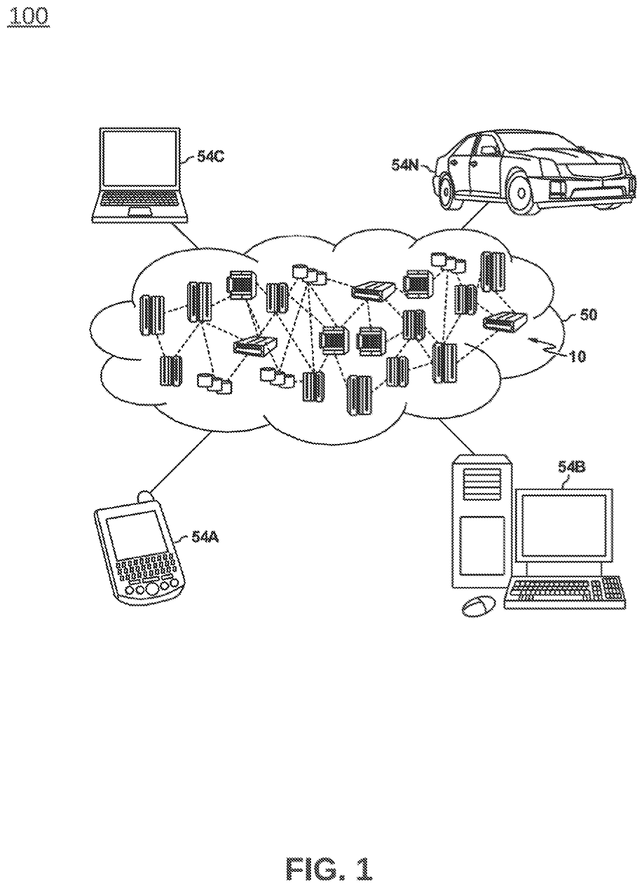

Referring now to FIG. 1, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Cloud computing nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 1 are intended to be illustrative only and that cloud computing nodes 10 and cloud computing environment 50 can communicate with any type of computerized device over any type of network and/or network addressable connection (e.g., using a web browser).

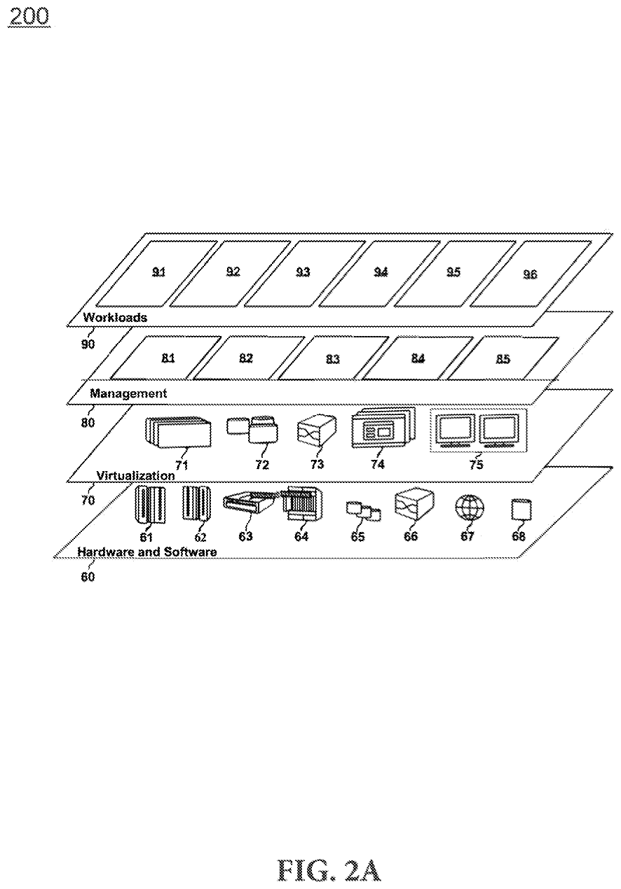

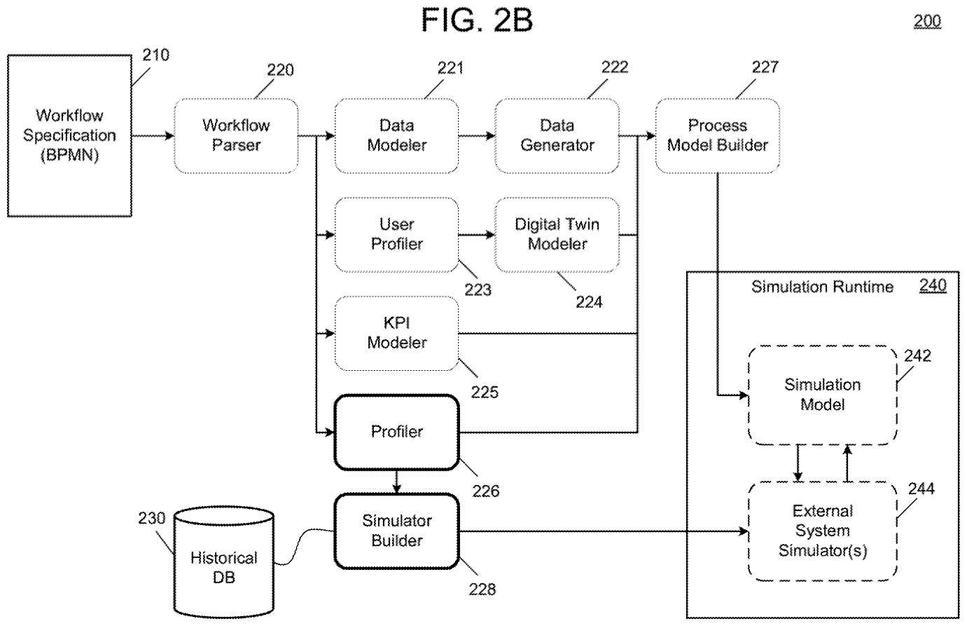

Referring now to FIG. 2A, a set of functional abstraction layers provided by cloud computing environment 50 FIG. 1) is shown. It should be understood in advance that the components, layers, and functions shown in FIG. 2A are intended to be illustrative only and embodiments of the invention are not limited thereto. As depicted, the following layers and corresponding functions are provided: Hardware and software layer 60 include hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68. Virtualization layer 70 provides an abstraction layer from which the following examples of virtual entities may be provided: virtual servers 71; virtual storage 72; virtual networks 73, including virtual private networks; virtual applications and operating systems 74; and virtual clients 75. In one example, management layer 80 may provide the functions described below.

Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workload layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and workflow simulation 96.

FIG. 2B illustrates an example of a process 200 corresponding to the workflow simulation 96 in FIG. 2A, in accordance with example embodiments. The process 200 may be executed by a host platform such as a web server, a cloud platform, a distributed group of computing systems, a database, and the like. Referring to FIG. 2B, the host platform may receive a workflow specification 210 as input. For example, the workflow specification 210 may include a Business Process Modeling Notation (BPMN) model of a process to be simulated. The BPMN model may include a structured format (e.g., JavaScript Objection Notation) which identifies each activity performed by the process and the input/outputs of each process.

For purposes of example, the process that may be embodied within the workflow specification 210 may include, but is not limited to, a credit lending workflow, a contingent labor procurement workflow, an automobile production workflow, and many others. These examples are further explained below.

When the workflow specification 210 is received by the system, a workflow parser 220 may parse the workflow specification 210 to identify a list of external systems (e.g., services) that provide input data to the business process as well as attributes of the external systems (e.g., inputs, outputs, function, etc.) For example, the workflow parser 220 may which activities within the workflow rely on an external service, a name of the service, an input data value/type to the service, an output data value/type from the service, and the like. In the example of the credit lending workflow, the external system may be a credit bureau that provides credit scores to the credit lending process which helps the process make a decision on whether to approve a loan. Here, the external system (i.e., the Credit Bureau), the input to the external system (e.g., a user's social security number, etc.), and an output from the external system (e.g., credit score of the user, etc.), can be identified by the workflow parser 220. The attributes obtained by the workflow parser 220 may be transferred to a profiler 227 and a simulator builder 228.

The parsed attributes may be delivered to a data modeler 221 which identifies data for simulating the process, a data generator 222 which generates the data for the simulation, a user profiler 223 which identifies user attributes of users of the process, a digital twin modeler 224 which can generate any digital twins of any assets, people, objects, etc. used in the simulation of the process, and a key performance indicator (KP) modeler 225 which identifies KPIs for the process. The data for simulating the process, the user attributes, the digital twins, and the KPIs may be fed to a process model builder 227 which can build a simulation model 242 for simulating the process based on the information fed from the other components of the system.

In addition, and according to various embodiments, the host system also implements a “dynamic” simulation system for a business workflow that is able to simulate the ever-changing environment of the business process based on the outcomes arising out of the simulation of the main business workflow. For example, in the case of credit lending use-case the external environment is simulated, which dynamically changes the credit scores of the customers based on the repayments patterns of the customers. Hence, the drawback that exists in a static simulation, where credit scores are sampled from a static distribution, can be alleviated through a dynamic simulation of environment.

In this example, the parsed attributes from the workflow parser 220 may also be transferred to a profiler 226 and a simulator builder 228, which are newly provided by the example embodiments and which can be used to implement the dynamic simulation. For example, the profiler 226 may receive the parsed information from the BPMN process flow identified by the workflow parser 220 and identify each activity related to an external system. For example, the profiler 226 may capture the input and output parameters regarding the external environment. The captured information may be passed to both the process model builder 227 for building the simulation model 242, and also to the simulator builder 228.

In this example, the simulator builder 228 may consume the information from the process model builder 227 and build a model (e.g., external system simulator 244) that simulates output values from the external system which are input to the process (simulation model 242). For example, the simulator builder 288 may build one or more machine learning (ML) models, one or more artificial intelligence (AI) models, a combination thereof, etc. which embody the external system simulator 244 and predict what values will be fed from the external system (e.g., the Credit Bureau in the example above) to the process (e.g., the loan approval process in the example above) based on historical actions between the external system and the process which are stored in a database 230.

To generate a simulation of a workflow of the process, the host platform may execute the simulation model 242 of the process and the external system simulator 244 within a simulation runtime 240 and generate a simulated workflow output/result. The simulation process may include executing both the simulation model 242 and the external system simulator 244 which simulates outputs from the external system which are input to the process, in parallel. Thus, predicted input values created by the external system simulator 244 may be passed as input variables to the simulation model 242 of the process which can be used instead of actual values from the external system which are often unavailable. The output of the simulation may be displayed on a user interface (not shown) and/or stored in a storage of the host platform and made accessible to users of the system.

The output obtained from the simulation of the external system helps to consider and understand how the external environment is changing and affecting the simulation of the main business workflow. Such an insight helps to proactively take appropriate actions to make the business workflow more robust to the changes in the external environment while achieving the designated goals/KPIs in the future.

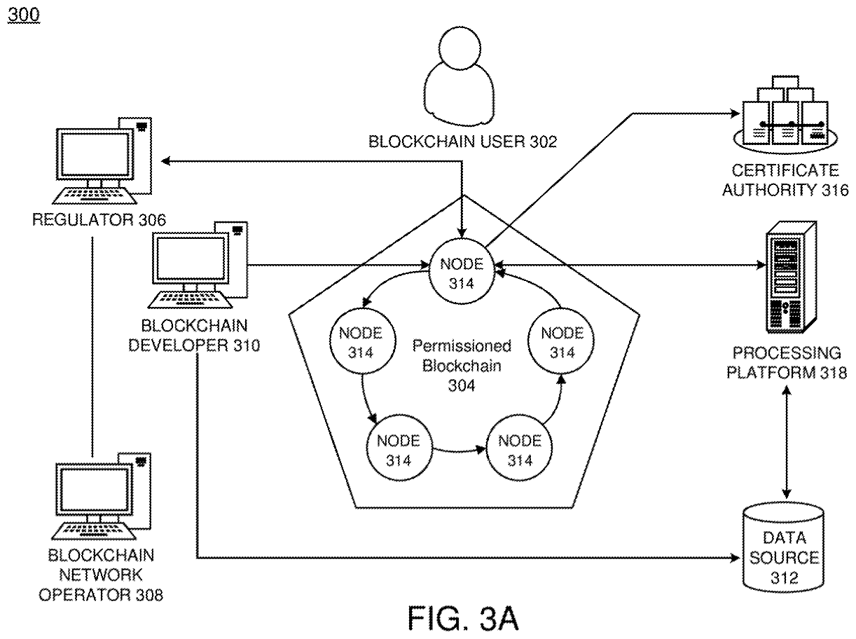

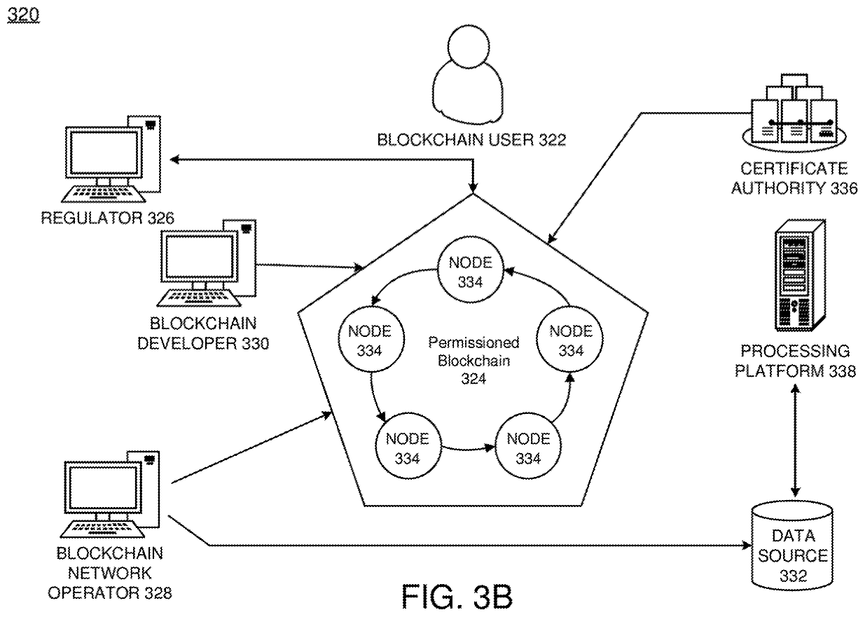

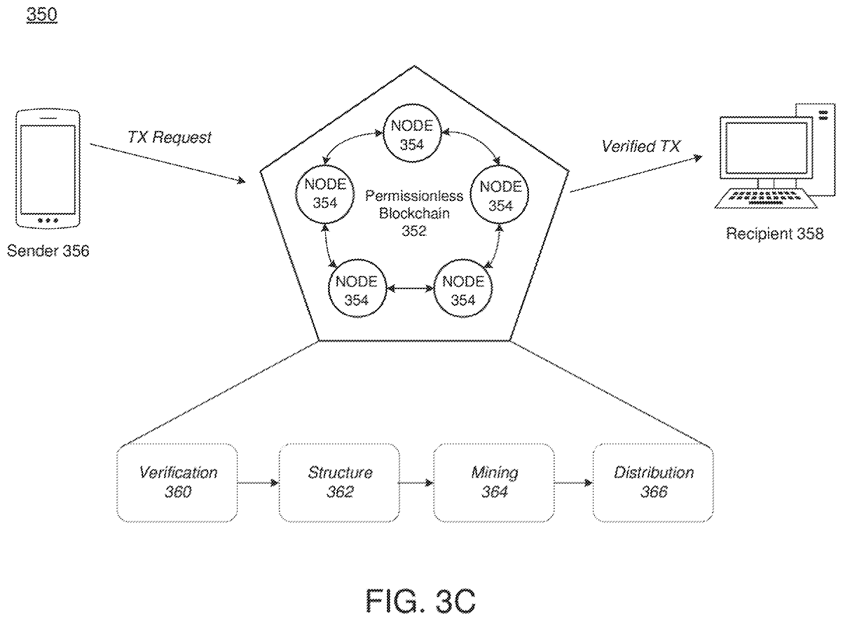

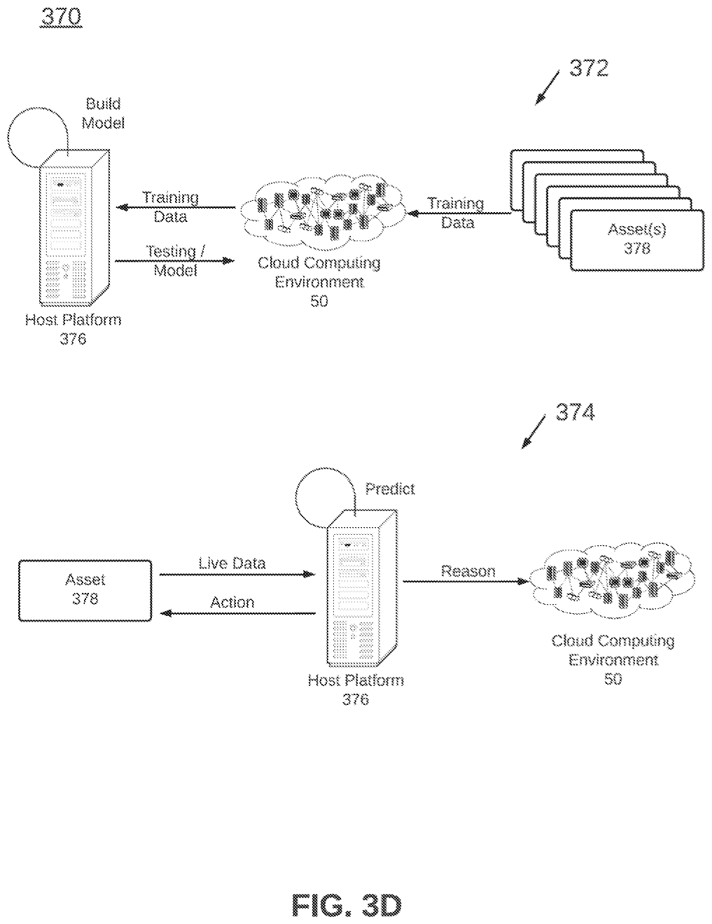

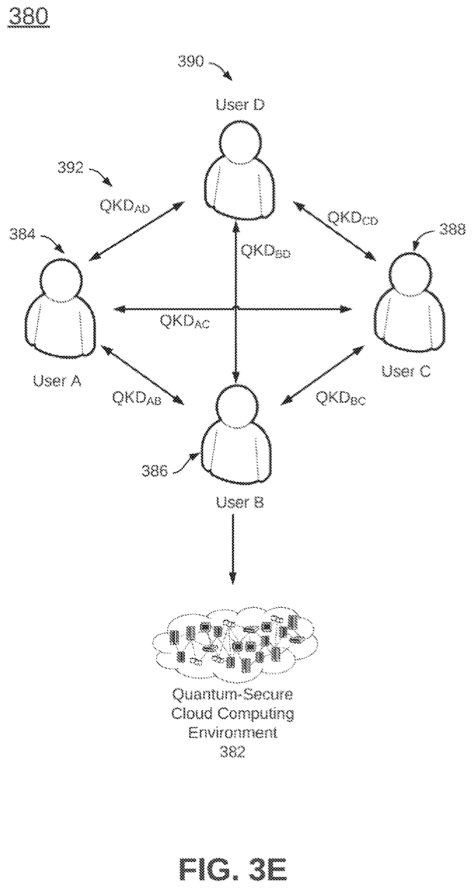

FIGS. 3A-3E provide various examples of additional features that may be used in association with the cloud computing environment described herein. These examples should be considered as additional extensions or additional examples of the embodiments described herein.

FIG. 3A illustrates an example of a permissioned blockchain network 300, which features a distributed, decentralized peer-to-peer architecture. The blockchain network may interact with the cloud computing environment 50, allowing additional functionality such as peer-to-peer authentication for data written to a distributed ledger. In this example, a blockchain user 302 may initiate a transaction to the permissioned blockchain 304. In this example, the transaction can be a deploy, invoke, or query, and may be issued through a client-side application leveraging an SDK, directly through an API, etc. Networks may provide access to a regulator 306, such as an auditor. A blockchain network operator 308 manages member permissions, such as enrolling the regulator 306 as an “auditor” and the blockchain user 302 as a “client”. An auditor could be restricted only to querying the ledger whereas a client could be authorized to deploy, invoke, and query certain types of chaincode.

A blockchain developer 310 can write chaincode and client-side applications. The blockchain developer 310 can deploy chaincode directly to the network through an interface. To include credentials from a traditional data source 312 in chaincode, the developer 310 could use an out-of-band connection to access the data. In this example, the blockchain user 302 connects to the permissioned blockchain 304 through a peer node 314. Before proceeding with any transactions, the peer node 314 retrieves the user's enrollment and transaction certificates from a certificate authority 316, which manages user roles and permissions. In some cases, blockchain users must possess these digital certificates in order to transact on the permissioned blockchain 304. Meanwhile, a user attempting to utilize chaincode may be required to verify their credentials on the traditional data source 312. To confirm the user's authorization, chaincode can use an out-of-band connection to this data through a traditional processing platform 318.

FIG. 3B illustrates another example of a permissioned blockchain network 320, which features a distributed, decentralized peer-to-peer architecture. In this example, a blockchain user 322 may submit a transaction to the permissioned blockchain 324. In this example, the transaction can be a deploy, invoke, or query, and may be issued through a client-side application leveraging an SDK, directly through an API, etc. Networks may provide access to a regulator 326, such as an auditor. A blockchain network operator 328 manages member permissions, such as enrolling the regulator 326 as an “auditor” and the blockchain user 322 as a “client”. An auditor could be restricted only to querying the ledger whereas a client could be authorized to deploy, invoke, and query certain types of chaincode.

A blockchain developer 330 writes chaincode and client-side applications. The blockchain developer 330 can deploy chaincode directly to the network through an interface. To include credentials from a traditional data source 332 in chaincode, the developer 330 could use an out-of-band connection to access the data. In this example, the blockchain user 322 connects to the network through a peer node 334. Before proceeding with any transactions, the peer node 334 retrieves the user's enrollment and transaction certificates from the certificate authority 336. In some cases, blockchain users must possess these digital certificates in order to transact on the permissioned blockchain 324. Meanwhile, a user attempting to utilize chaincode may be required to verify their credentials on the traditional data source 332. To confirm the user's authorization, chaincode can use an out-of-band connection to this data through a traditional processing platform 338.

In some embodiments, the blockchain herein may be a permissionless blockchain. In contrast with permissioned blockchains which require permission to join, anyone can join a permissionless blockchain. For example, to join a permissionless blockchain a user may create a personal address and begin interacting with the network, by submitting transactions, and hence adding entries to the ledger. Additionally, all parties have the choice of running a node on the system and employing the mining protocols to help verify transactions.

FIG. 3C illustrates a process 350 of a transaction being processed by a permissionless blockchain 352 including a plurality of nodes 354. A sender 356 desires to send payment or some other form of value (e.g., a deed, medical records, a contract, a good, a service, or any other asset that can be encapsulated in a digital record) to a recipient 358 via the permissionless blockchain 352. In one embodiment, each of the sender device 356 and the recipient device 358 may have digital wallets (associated with the blockchain 352) that provide user interface controls and a display of transaction parameters. In response, the transaction is broadcast throughout the blockchain 352 to the nodes 354. Depending on the blockchain's 352 network parameters the nodes verify 360 the transaction based on rules (which may be pre-defined or dynamically allocated) established by the permissionless blockchain 352 creators. For example, this may include verifying identities of the parties involved, etc. The transaction may be verified immediately or it may be placed in a queue with other transactions and the nodes 354 determine if the transactions are valid based on a set of network rules.

In structure 362, valid transactions are formed into a block and sealed with a lock (hash). This process may be performed by mining nodes among the nodes 354. Mining nodes may utilize additional software specifically for mining and creating blocks for the permissionless blockchain 352. Each block may be identified by a hash (e.g., 256 bit number, etc.) created using an algorithm agreed upon by the network. Each block may include a header, a pointer or reference to a hash of a previous block's header in the chain, and a group of valid transactions. The reference to the previous block's hash is associated with the creation of the secure independent chain of blocks.

Before blocks can be added to the blockchain, the blocks must be validated. Validation for the permissionless blockchain 352 may include a proof-of-work (PoW) which is a solution to a puzzle derived from the block's header. Although not shown in the example of FIG. 3C, another process for validating a block is proof-of-stake. Unlike the proof-of-work, where the algorithm rewards miners who solve mathematical problems, with the proof of stake, a creator of a new block is chosen in a deterministic way, depending on its wealth, also defined as “stake.” Then, a similar proof is performed by the selected/chosen node.

With mining 364, nodes try to solve the block by making incremental changes to one variable until the solution satisfies a network-wide target. This creates the PoW thereby ensuring correct answers. In other words, a potential solution must prove that computing resources were drained in solving the problem. In some types of permissionless blockchains, miners may be rewarded with value (e.g., coins, etc.) for correctly mining a block.

Here, the PoW process, alongside the chaining of blocks, makes modifications of the blockchain extremely difficult, as an attacker must modify all subsequent blocks in order for the modifications of one block to be accepted. Furthermore, as new blocks are mined, the difficulty of modifying a block increases, and the number of subsequent blocks increases. With distribution, the successfully validated block is distributed through the permissionless blockchain 352 and all nodes 354 add the block to a majority chain which is the permissionless blockchain's 352 auditable ledger. Furthermore, the value in the transaction submitted by the sender 356 is deposited or otherwise transferred to the digital wallet of the recipient device 358.

FIGS. 3D and 3E illustrate additional examples of use cases for cloud computing that may be incorporated and used herein. FIG. 3D illustrates an example 370 of a cloud computing environment 50 which stores machine learning (artificial intelligence) data. Machine learning relies on vast quantities of historical data (or training data) to build predictive models for accurate prediction on new data. Machine learning software (e.g., neural networks, etc.) can often sift through millions of records to unearth non-intuitive patterns.

In the example of FIG. 3D, a host platform 376 builds and deploys a machine learning model for predictive monitoring of assets 378. Here, the host platform 366 may be a cloud platform, an industrial server, a web server, a personal computer, a user device, and the like. Assets 378 can be any type of asset (e.g., machine or equipment, etc.) such as an aircraft, locomotive, turbine, medical machinery and equipment, oil and gas equipment, boats, ships, vehicles, and the like. As another example, assets 378 may be non-tangible assets such as stocks, currency, digital coins, insurance, or the like.

The cloud computing environment 50 can be used to significantly improve both a training process 372 of the machine learning model and a predictive process 374 based on a trained machine learning model. For example, in 372, rather than requiring a data scientist/engineer or another user to collect the data, historical data may be stored by the assets 378 themselves (or through an intermediary, not shown) on the cloud computing environment 50. This can significantly reduce the collection time needed by the host platform 376 when performing predictive model training. For example, data can be directly and reliably transferred straight from its place of origin to the cloud computing environment 50. By using the cloud computing environment 50 to ensure the security and ownership of the collected data, smart contracts may directly send the data from the assets to the individuals that use the data for building a machine learning model. This allows for sharing of data among the assets 378.

Furthermore, training of the machine learning model on the collected data may take rounds of refinement and testing by the host platform 376. Each round may be based on additional data or data that was not previously considered to help expand the knowledge of the machine learning model. In 372, the different training and testing steps (and the data associated therewith) may be stored on the cloud computing environment 50 by the host platform 376. Each refinement of the machine learning model (e.g., changes in variables, weights, etc.) may be stored in the cloud computing environment 50 to provide verifiable proof of how the model was trained and what data was used to train the model. For example, the machine learning model may be stored on a blockchain to provide verifiable proof. Furthermore, when the host platform 376 has achieved a trained model, the resulting model may be stored on the cloud computing environment 50.

After the model has been trained, it may be deployed to a live environment where it can make predictions/decisions based on the execution of the final trained machine learning model. For example, in 374, the machine learning model may be used for condition-based maintenance (CBM) for an asset such as an aircraft, a wind turbine, a healthcare machine, and the like. In this example, data fed back from asset 378 may be input into the machine learning model and used to make event predictions such as failure events, error codes, and the like. Determinations made by the execution of the machine learning model at the host platform 376 may be stored on the cloud computing environment 50 to provide auditable/verifiable proof. As one non-limiting example, the machine learning model may predict a future breakdown/failure to a part of the asset 378 and create an alert or a notification to replace the part. The data behind this decision may be stored by the host platform 376 and/or on the cloud computing environment 50. In one embodiment the features and/or the actions described and/or depicted herein can occur on or with respect to the cloud computing environment 50.

FIG. 3E illustrates an example 380 of a quantum-secure cloud computing environment 382, which implements quantum key distribution (QKD) to protect against a quantum computing attack. In this example, cloud computing users can verify each other's identities using QKD. This sends information using quantum particles such as photons, which cannot be copied by an eavesdropper without destroying them. In this way, a sender, and a receiver through the cloud computing environment can be sure of each other's identity.

In the example of FIG. 3E, four users are present 384, 386, 388, and 390. Each pair of users may share a secret key 392 (i.e., a QKD) between themselves. Since there are four nodes in this example, six pairs of nodes exist, and therefore six different secret keys 392 are used including QKD_{AB}, QKD_{AC}, QKD_{AD}, QKD_{BC}, QKD_{BD}, and QKD_{CD}. Each pair can create a QKD by sending information using quantum particles such as photons, which cannot be copied by an eavesdropper without destroying them. In this way, a pair of users can be sure of each other's identity.

The operation of the cloud computing environment 382 is based on two procedures (i) creation of transactions, and (ii) construction of blocks that aggregate the new transactions. New transactions may be created similar to a traditional network, such as a blockchain network. Each transaction may contain information about a sender, a receiver, a time of creation, an amount (or value) to be transferred, a list of reference transactions that justifies the sender has funds for the operation, and the like. This transaction record is then sent to all other nodes where it is entered into a pool of unconfirmed transactions. Here, two parties (i.e., a pair of users from among 384-390) authenticate the transaction by providing their shared secret key 392 (QKD). This quantum signature can be attached to every transaction making it exceedingly difficult to be tampered with. Each node checks its entries with respect to a local copy of the cloud computing environment 382 to verify that each transaction has sufficient funds.

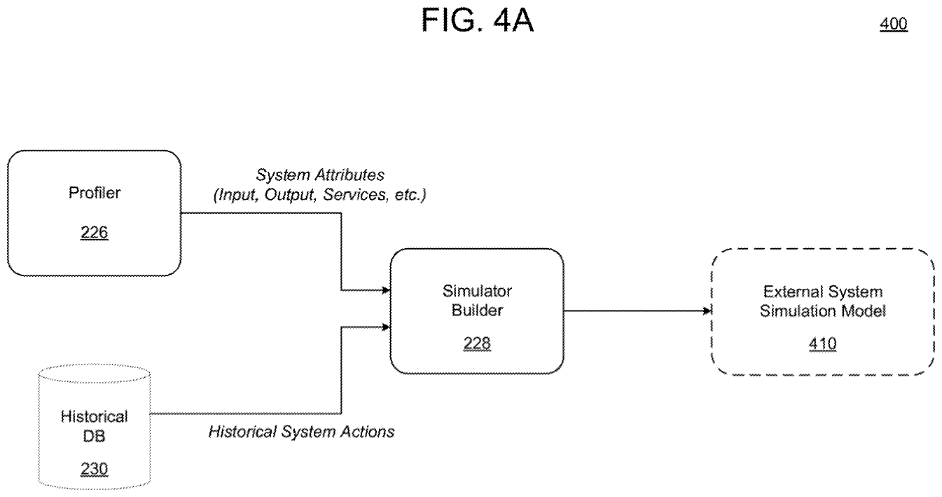

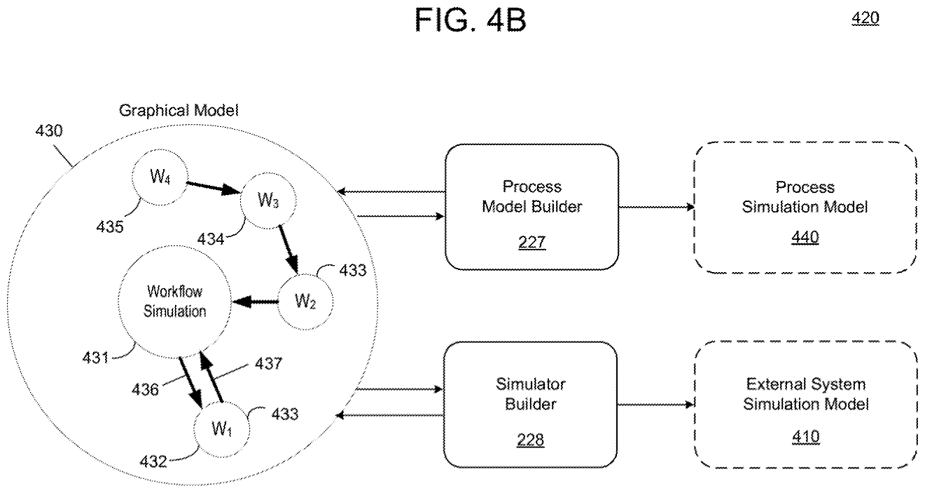

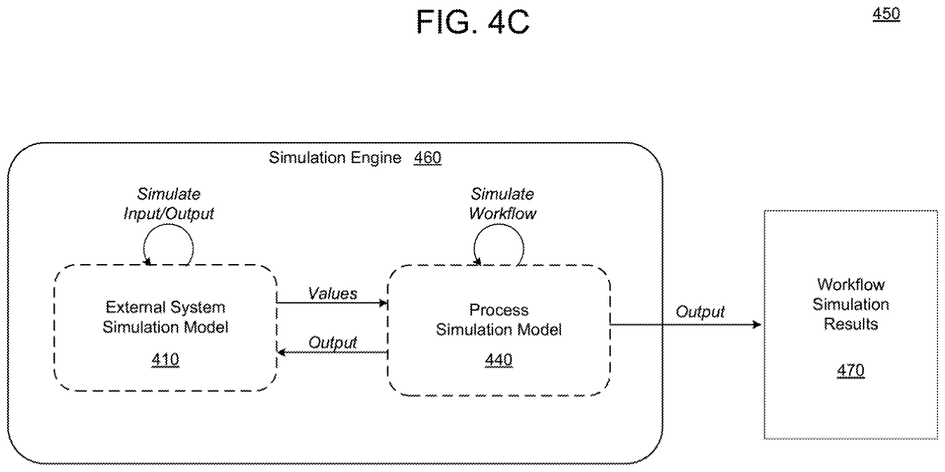

FIGS. 4A-4C are diagrams illustrating various examples of simulating an environment in which a simulated workflow occurs and feeding values from the simulated environment to the process being simulated. For a simulation it is essential to build the environment which affects the actual simulation. However, often it is not possible to get the data on the attributes of the environment in a timely manner/or needs to be procured which is costly. Hence, the example embodiments can predict the values of such external variables within the simulator builder.

The profiler described in FIG. 2B may identify which external systems are actually affected by the simulation output. For example, there may be multiple external systems which feed data to the process during the simulation. However, not all of the external systems may be affected by the output of the simulation. For example, in the case of a loan application approval process, a user's credit score may change over time as a result of changes to the user's credit history. These changes to credit scores may be affected by the results of the lending approval process which will approve loans/deny loans and cause additional changes to credit scores as a result. Thus, there is an interdependence between the credit score (input variable) fed by the external system to the process, and the output (loan approval/denial) that can cause the credit score to go up or down. As another example, an external system that supplies account history information (spending history) is not subject to interdependence with the loan approval process since it is not directly or indirectly affected by the loan approval.

Therefore, when analyzing external systems and the attributes/input values that they provide to the process being simulated, the external systems can be divided into two types include a first type that provides/pass attributes to the simulating process on a periodic basis for simulation of the workflow but which are not affected by the output of the simulated process. The second type of external system provide/pass attributes to the simulating process that are affected by/interdependent with the output of the simulation. These attributes may be passed directly to the process or indirectly (via another external system, etc.) The profiler can use external APIs identified from the workflow specification (e.g., BPMN model, etc.) to gather data for these attributes and such APIs can be triggered by the workflow simulation on a periodic basis or as provided to the simulation through a third-party application. For these interdependent external systems, the host platform can generate simulators (predictive models) configured to predict future values of the attribute to be passed to the simulation. One of the benefits of such simulators is that the input values can be generated using predictive means even when such input values are not provided by the external system.

It should also be appreciated that there can be multiple attributes which affect the workflow simulation and vice versa. However, the effect of such attributes may not be the same. As further described below, the host platform may generate a graphical model which can be passed into the simulation for capturing the effect of the attributes. In particular, the graphical model can provide hops/distances between an attribute (provided by an external system) and the process being simulated.

FIG. 4A illustrates a process 400 of building an external system simulation model 410 according to an example embodiment. Referring to FIG. 4A, the profiler 226 may transfer attributes of the external system (e.g., input model, output model, type of service, etc.) to the simulator builder 228. In addition, previous actions performed by the external service may be pulled from the database 230 and used to train a model such as an external system simulation model 410 (also referred to herein as a simulator). The host platform may involve iteratively execute a predictive model (e.g., a machine learning model(s), an artificial intelligence model(s), a combination thereof, etc.) on the historical data to generate the external system simulation model 410 that can predict an action/output by the external system. The output type may be based on the data attributes provided by the profiler 226.

As previously noted, the external system may provide attribute values to a workflow simulation. In a first scenario, the actual values of the external attributes are available. In this scenario, the model (e.g., external system simulation model 410, etc.) may be created using a predefined function (ML algorithm, AI algorithm, etc.) For example, the function may determine a final input value based on the attribute and a number of hops between the external system outputting the attribute value and the workflow simulation. Here, the function may be monotonically non increasing even when the number of hops increase. The predictive function may be embodied within the external system simulation model 410 and used to predict values from the external system which are input to the process/workflow being simulated.

In a second scenario, some of the actual values of the external system are not completely available from the historical data. In this case, the simulator (e.g., external system simulation model 410, etc.) may predict the future values of the external system that are input to the simulation based on historical data values/actions pulled from the database 230. The model may be trained to identify an interdependence between the input value from the external system and the output result by the simulation. Furthermore, the number of hops between the external system outputting the attribute value and the workflow simulation may also be built into the external system simulation model 410 and used to predict output values of the external system which are input to the workflow simulation.

In a third scenario, the values output by the external system and input to the workflow simulation are affected by both the output of the simulation and another external system/attribute passed to the workflow simulation. In this case, the number of hops between the external system and the workflow simulation and the number of hopes between the another external system and the external system, are used to predict output values for the external system which are input to the workflow simulation.

In a fourth scenario, all of the values of the external system are unavailable. In this case, the host platform can still build a predictive model for the external system using interdependence between the attribute value output by the external system and attribute values output by one or more other external systems, and the number of hops between the external system and the one or more other external systems.

FIG. 4B illustrates a process 420 of identifying hops between attributes and a workflow simulation using a graphical model 430 according to an example embodiment. Referring to the example of FIG. 4B, the host platform may build the graphical model 430 representing the flow of attribute values into the process being simulated. In this example, a node 431 in the graphical model 430 represents a workflow simulation of the process/business process. In some embodiments, the node 431 may be positioned at or near a center of the graphical model 430. Meanwhile, nodes 432, 433, 434, and 435 may be positioned around the node 431 and may be used to represent external systems and the respective attributes (W₁, W₂, W₃, and W₄) which they provide to the process being simulated at node 431, respectively. Thus, the workflow simulation is dependent on input values of the four attributes W₁, W₂, W₃, and W₄ in this example. The graphical model 430 may be generated by process mining a live instance of the process being executed on the host platform. As another example, the graphical model 430 can be generated from the workflow specification/BPMN model that is uploaded to the host platform, or the like.

According to various embodiments, the graphical model 430 can be used to identify interdependencies and number of hops between the different external systems and the workflow simulation itself. The graphical model 430 also provides a direction of the dependency relationships using arrows. In the example shown in FIG. 4B, a first external system generates an attribute value (W₁) represented by node 432. This attribute value (W₁) is input to the workflow during a simulation as noted by an arrow 436 between the node 432 and the central node 431. Likewise, the output of the workflow simulation 431 is input back into the external system as noted by arrow 437. This bi-directional interdependence can be identified from the graphical model 430 and used to select the appropriate modeling scenario from FIG. 4A.

The process model builder 227 shown in FIG. 2B may query the graphical model 430 for the workflow steps which can be used to build a process simulation model 440 for simulating a workflow of the process (represented by node 431). Likewise, the simulator builder 228 may query the graphical model for hops between externals systems and/or the workflow simulation 431, and use these hops to build external system simulation model 410 (which may be multiple models for multiple external systems, respectively). The number of hops may be determined based on a distance between the external system and the node 431 representing the workflow simulation. For example, external system that creates the fourth attribute (W₄) represented by node 435 is three hops away from the workflow simulation node 431, while the second attributes (W₂) represented by node 433 is only one hop away from the workflow simulation node 431. Meanwhile, the node 435 and the node 433 are two hops away from each other. The hops may be incorporated into the predictive models that embody the simulator (external system simulation model 410) as described in the example of FIG. 4A.

FIG. 4C illustrates a process 450 of simulating a workflow for a process according to an example embodiment. Referring to FIG. 4C, the host platform may deploy an instance of the external system simulation model 410 (or models) within a simulation runtime environment. In addition, the host platform may deploy an instance of the process simulation model 440. In some embodiments, although not required, the external system simulation model 410 and the process simulation model 440 may be executed together (simultaneously, in parallel, etc.) and allowed to interact with one another to enable values to be passed between the two models. A simulated output 470 can be generated and output from the result of the simulation process including the interaction between the external system simulation model 410 and the process simulation model 440.

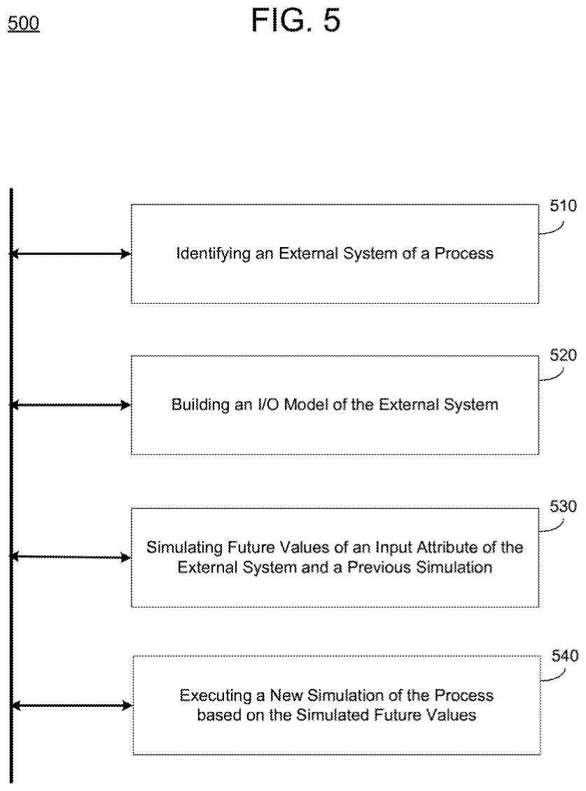

FIG. 5 illustrates a method 500 of simulating a workflow based on a simulated workflow environment according to an example embodiment. For example, the method 500 may be performed by a computer system such as a cloud platform, a web server, a personal computer or other user device, and the like. Referring to FIG. 5, in 510 the method may include identifying an external system that passes an input attribute to a process based on a workflow representation of the process.

In 520, the method may include building an input-output (I/O) model of the external system based on attributes of the external system identified from the workflow representation. In 530, the method may include simulating future values of the input attribute to be passed to the process by the external system based on the I/O model of the external system and a previous simulation run of the process performed via a workflow software application. In 540, the method may include executing a new simulation of the process via the workflow software application based on the simulated future values of the input attribute.

In some embodiments, the identifying may include identifying an input to the external system, an output from the external system, and one or more services performed by the external system. In some embodiments, the building the I/O model may include building at least one of an artificial intelligence (AI) model and a machine learning (ML) model for predicting the future values of the input attribute based on the attributes of the external system identified from the workflow representation.

In some embodiments, the method may further include building a graphical model for the process that includes a central node representing a workflow simulation of the process, a plurality of external nodes which represent a plurality of input attributes to the workflow simulation, and edges between the plurality nodes and the central node which represent hops from the plurality of input attributes to the workflow simulation. In some embodiments, the simulating the future values of the input attribute to be passed to the process by the external system may be performed based on a number of hops between a node that represents the input attribute in the graphical model and the central node in the graphical model.

In some embodiments, the identifying may include identifying the external system based on an interdependence between an input of the external system and an output of the workflow simulation within the graphical model. In some embodiments, the identifying may include parsing a business process model notation (BPMN) model of the workflow representation to identify the external system, identify an input to the external system, and identify an output from the external system. In some embodiments, the executing the new simulation of the process via the workflow software application may be based on available future values of another input attribute from another external system of the process.

The above embodiments may be implemented in hardware, in a computer program executed by a processor, in firmware, or in a combination of the above. A computer program may be embodied on a computer readable medium, such as a storage medium. For example, a computer program may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of storage medium known in the art.

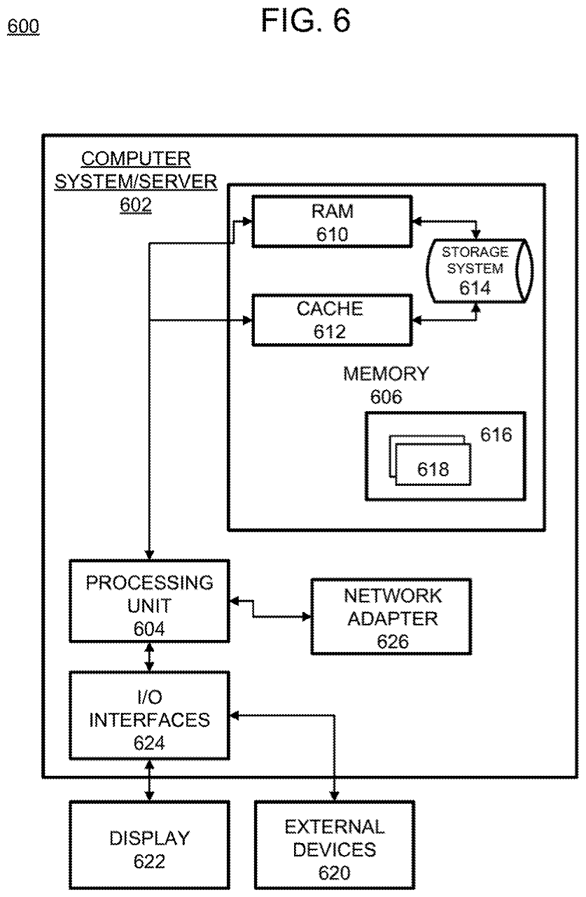

An exemplary storage medium may be coupled to the processor such that the processor may read information from, and write information to, the storage medium. In the alternative, the storage medium may be integral to the processor. The processor and the storage medium may reside in an application specific integrated circuit (“ASIC”). In the alternative, the processor and the storage medium may reside as discrete components. For example, FIG. 6 illustrates an example computer system architecture 600, which may represent or be integrated in any of the above-described components, etc.

FIG. 6 illustrates an example system 600 that supports one or more of the example embodiments described and/or depicted herein. The system 600 comprises a computer system/server 602, which is operational with numerous other general purpose or special purpose computing system environments or configurations. Examples of well-known computing systems, environments, and/or configurations that may be suitable for use with computer system/server 602 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 602 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 602 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 6, computer system/server 602 in cloud computing node 600 is shown in the form of a general-purpose computing device. The components of computer system/server 602 may include, but are not limited to, one or more processors or processing units 604, a system memory 606, and a bus that couples various system components including system memory 606 to processor 604.

The bus represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 602 typically includes a variety of computer system readable media. Such media may be any available media that is accessible by computer system/server 602, and it includes both volatile and non-volatile media, removable and non-removable media. System memory 606, in one embodiment, implements the flow diagrams of the other figures. The system memory 606 can include computer system readable media in the form of volatile memory, such as random-access memory (RAM) 610 and/or cache memory 612. Computer system/server 602 may further include other removable/non-removable, volatile/non-volatile computer system storage media. By way of example only, storage system 614 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to the bus by one or more data media interfaces. As will be further depicted and described below, memory 606 may include at least one program product having a set (e.g., at least one) of program modules that are configured to carry out the functions of various embodiments of the application.

Program/utility 616, having a set (at least one) of program modules 618, may be stored in memory 606 by way of example, and not limitation, as well as an operating system, one or more application programs, other program modules, and program data. Each of the operating system, one or more application programs, other program modules, and program data or some combination thereof, may include an implementation of a networking environment. Program modules 618 generally carry out the functions and/or methodologies of various embodiments of the application as described herein.

As will be appreciated by one skilled in the art, aspects of the present application may be embodied as a system, method, or computer program product. Accordingly, aspects of the present application may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present application may take the form of a computer program product embodied in one or more computer readable medium(s) having computer readable program code embodied thereon.

Computer system/server 602 may also communicate with one or more external devices 620 such as a keyboard, a pointing device, a display 622, etc.; one or more devices that enable a user to interact with computer system/server 602; and/or any devices (e.g., network card, modem, etc.) that enable computer system/server 602 to communicate with one or more other computing devices. Such communication can occur via I/O interfaces 624. Still yet, computer system/server 602 can communicate with one or more networks such as a local area network (LAN), a general wide area network (WAN), and/or a public network (e.g., the Internet) via network adapter 626. As depicted, network adapter 626 communicates with the other components of computer system/server 602 via a bus. It should be understood that although not shown, other hardware and/or software components could be used in conjunction with computer system/server 602. Examples, include, but are not limited to: microcode, device drivers, redundant processing units, external disk drive arrays, RAID systems, tape drives, and data archival storage systems, etc.

Although an exemplary embodiment of at least one of a system, method, and non-transitory computer readable medium has been illustrated in the accompanied drawings and described in the foregoing detailed description, it will be understood that the application is not limited to the embodiments disclosed, but is capable of numerous rearrangements, modifications, and substitutions as set forth and defined by the following claims. For example, the capabilities of the system of the various figures can be performed by one or more of the modules or components described herein or in a distributed architecture and may include a transmitter, receiver or pair of both. For example, all or part of the functionality performed by the individual modules, may be performed by one or more of these modules. Further, the functionality described herein may be performed at various times and in relation to various events, internal or external to the modules or components. Also, the information sent between various modules can be sent between the modules via at least one of: a data network, the Internet, a voice network, an Internet Protocol network, a wireless device, a wired device and/or via plurality of protocols. Also, the messages sent or received by any of the modules may be sent or received directly and/or via one or more of the other modules.

One skilled in the art will appreciate that a “system” could be embodied as a personal computer, a server, a console, a personal digital assistant (PDA), a cell phone, a tablet computing device, a smartphone or any other suitable computing device, or combination of devices. Presenting the above-described functions as being performed by a “system” is not intended to limit the scope of the present application in any way but is intended to provide one example of many embodiments. Indeed, methods, systems and apparatuses disclosed herein may be implemented in localized and distributed forms consistent with computing technology.

It should be noted that some of the system features described in this specification have been presented as modules, in order to more particularly emphasize their implementation independence. For example, a module may be implemented as a hardware circuit comprising custom very large-scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices, graphics processing units, or the like.

A module may also be at least partially implemented in software for execution by various types of processors. An identified unit of executable code may, for instance, comprise one or more physical or logical blocks of computer instructions that may, for instance, be organized as an object, procedure, or function. Nevertheless, the executables of an identified module need not be physically located together but may comprise disparate instructions stored in different locations which, when joined logically together, comprise the module and achieve the stated purpose for the module. Further, modules may be stored on a computer-readable medium, which may be, for instance, a hard disk drive, flash device, random access memory (RAM), tape, or any other such medium used to store data.

Indeed, a module of executable code could be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different storage devices, and may exist, at least partially, merely as electronic signals on a system or network.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent.

While preferred embodiments of the present application have been described, it is to be understood that the embodiments described are illustrative only and the scope of the application is to be defined solely by the appended claims when considered with a full range of equivalents and modifications (e.g., protocols, hardware devices, software platforms etc.) thereto.

What is claimed is:

1. An apparatus comprising:
a memory configured to store a workflow software application; and
a processor configured to
identify an external system that passes an input attribute to a process based on a workflow representation of the process;
build a simulator of the external system based on attributes of the external system identified from the workflow representation;
simulate future values of the input attribute to be passed to the process by the external system based on the simulator of the external system and a previous workflow simulation of the process performed via a workflow software application; and
execute a new workflow simulation of the process via the workflow software application based on the simulated future values of the input attribute.

2. The apparatus of claim 1, wherein the processor is configured to identify an input to the external system, an output from the external system, and one or more services performed by the external system.

3. The apparatus of claim 1, wherein the simulator comprises at least one of an artificial intelligence (AI) model and a machine learning (ML) model that is generated based on the attributes of the external system identified from the workflow representation, and the processor is configured to simulate the future values of the input attribute based on the at least one of the AI model and the ML model.

4. The apparatus of claim 1, wherein the processor is configured to build a graphical model for the process that includes a central node that represents a workflow simulation of the process, a plurality of external nodes that represent a plurality of input attributes to the workflow simulation, and edges between the plurality nodes and the central node which represent hops from the plurality of input attributes to the workflow simulation.

5. The apparatus of claim 4, wherein the processor is further configured to simulate the future values of the input attribute to be passed to the process by the external system via the simulator based on a number of hops between a node that represents the input attribute in the graphical model and the central node in the graphical model.

6. The apparatus of claim 4, wherein the processor is configured to identify the external system based on an interdependence between an input of the external system and an output of the workflow simulation within the graphical model.

7. The apparatus of claim 1, wherein the processor is configured to parse a business process model notation (BPMN) model of the workflow representation to identify the external system, an input to the external system, and an output from the external system.

8. The apparatus of claim 1, wherein the processor is further configured to execute the new simulation of the process via the workflow software application based on available future values of another input attribute from another external system of the process.

9. A method comprising:
identifying an external system that passes an input attribute to a process based on a workflow representation of the process;
building a simulator of the external system based on attributes of the external system identified from the workflow representation;
simulating future values of the input attribute to be passed to the process by the external system based on the simulator of the external system and a previous simulation run of the process performed via a workflow software application; and
executing a new simulation of the process via the workflow software application based on the simulated future values of the input attribute.

10. The method of claim 9, wherein the identifying comprises identifying an input to the external system, an output from the external system, and one or more services performed by the external system.

11. The method of claim 9, wherein the simulator comprises at least one of an artificial intelligence (AI) model and a machine learning (ML) model that is generated based on the attributes of the external system identified from the workflow representation, and the simulating comprises simulating the future values of the input attribute based on the at least one of the AI model and the ML model.

12. The method of claim 9, wherein the method further comprises building a graphical model for the process that includes a central node representing a workflow simulation of the process, a plurality of external nodes which represent a plurality of input attributes to the workflow simulation, and edges between the plurality nodes and the central node which represent hops from the plurality of input attributes to the workflow simulation.

13. The method of claim 12, wherein the simulating the future values of the input attribute to be passed to the process by the external system is performed based on a number of hops between a node that represents the input attribute in the graphical model and the central node in the graphical model.

14. The method of claim 12, wherein the identifying comprises identifying the external system based on an interdependence between an input of the external system and an output of the workflow simulation within the graphical model.

15. The method of claim 9, wherein the identifying comprises parsing a business process model notation (BPMN) model of the workflow representation to identify the external system, identify an input to the external system, and identify an output from the external system.

16. The method of claim 9, wherein the executing the new simulation of the process via the workflow software application is further based on available future values of another input attribute from another external system of the process.

17. A computer-readable storage medium comprising instructions, that when read by a processor, cause the processor to perform a method comprising:
identifying an external system that passes an input attribute to a process based on a workflow representation of the process;
building a simulator of the external system based on attributes of the external system identified from the workflow representation;
simulating future values of the input attribute to be passed to the process by the external system based on the simulator of the external system and a previous simulation run of the process performed via a workflow software application; and
executing a new simulation of the process via the workflow software application based on the simulated future values of the input attribute.

18. The computer-readable storage medium of claim 17, wherein the identifying comprises identifying an input to the external system, an output from the external system, and one or more services performed by the external system.

19. The computer-readable storage medium of claim 17, wherein the simulator comprises at least one of an artificial intelligence (AI) model and a machine learning (ML) model that is generated based on the attributes of the external system identified from the workflow representation, and the simulating comprises simulating the future values of the input attribute based on the at least one of the AI model and the ML model.

20. The computer-readable storage medium of claim 17, wherein the executing the new simulation of the process via the workflow software application is further based on available future values of another input attribute from another external system of the process.
